(19) United States
(12) Patent Application Publication
(10) Pub. No.: US 2026/0033147 A1
(43) Pub. Date: Jan. 29, 2026

(54) DISPLAY PANEL AND DISPLAY DEVICE

(71) Applicant: HKC CORPORATION LIMITED, SHENZHEN (CN)

(72) Inventors: Jie CHEN, SHENZHEN (CN); Zhonglin CAO, SHENZHEN (CN); Chuan WU, SHENZHEN (CN); Xiaoxiao YUAN, SHENZHEN (CN); Wenyu YI, SHENZHEN (CN); Dongmei WEI, SHENZHEN (CN); Fengzhen DANG, SHENZHEN (CN); Yao LI, SHENZHEN (CN); Lidan YE, SHENZHEN (CN)

(73) Assignee: HKC CORPORATION LIMITED, SHENZHEN (CN)

(21) Appl. No.: 19/253,727

(22) Filed: Jun. 28, 2025

(30) Foreign Application Priority Data
Jul. 23, 2024 (CN) 202410994762.1

(51) Int. Cl. H10K 59/122; H10K 59/127; H10K 59/35; H10K 59/80

(52) U.S. Cl. CPC H10K 59/122; H10K 59/1275; H10K 59/352; H10K 59/353; H10K 59/80515; H10K 59/80521

(57) ABSTRACT

A display panel includes: a silicon-based driver substrate; and a light emitting carrier board bonded thereto. The light emitting carrier board includes: a glass substrate, having cathode through holes; a pixel defining layer, arranged on the glass substrate and having pixel openings; sub-pixels, arranged in the pixel openings. Each sub-pixel includes an anode layer, a light emitting layer and a cathode layer. Isolation structures protrude out of the pixel defining layer. Each isolation structure is disposed between two adjacent sub-pixels of different colors. Each isolation structure includes a top structure and a conductive portion lapped with the cathode layer. The light emitting carrier board further includes a cathode auxiliary layer. The conductive portion extends through the pixel defining layer to be electrically connected to the cathode auxiliary layer; the cathode auxiliary layer extends through the cathode through holes to be electrically connected to the silicon-based driver substrate.

### CROSS REFERENCE TO RELATED APPLICATIONS

The present application claims the priority of the Chinese patent application No. 202410994762.1, filed on Jul. 23, 2024, contents of which are incorporated herein by its entireties.

### TECHNICAL FIELD

Embodiments of the present disclosure relate to the technical field of displaying, and more specifically, to a display panel and a display device.

### BACKGROUND

A silicon-based micro-display takes a monocrystalline silicon as a substrate, a back plane of the silicon-based micro-display is integrated with driver circuits made by a Complementary Metal-Oxide-Semiconductor (CMOS) process. Higher integration is achieved, and top-emission is the substantial configuration.

A silicon-based Organic Light Emitting Display (OLED) is a type of display device having best performance for Augmented Reality (AR)/Virtual Reality (VR). Compared to a conventional Active-Matrix Organic Light-Emitting Diodes (AMOLED), which is arranged with a back plate made of amorphous silicon, microcrystalline silicon, or low-temperature polycrystalline silicon thin-film transistors, a monocrystalline silicon back plate has a higher carrier mobility. Vaporization is performed on the silicon-based CMOS driver substrate to form a pixel pattern isolation layer, and an anode, an organic layer, and a cathode are further vaporized, so as to prepare a smaller sized pixel, such that refinement of displaying pixels can be achieved.

However, during vaporization to obtain sub-pixels, the silicon-based driver circuit may be affected, silicon-based driver circuits may be unusable, increasing manufacturing costs.

### SUMMARY

The present disclosure provides a display panel and a display device, so as to solve the technical problem of a silicon-based driver circuit layer being affected during vaporization to obtain sub-pixels.

In a first aspect, the present disclosure provides a display panel, including:
a silicon-based driver substrate;
a light emitting carrier board, bonded and connected to the silicon-based driver substrate; where the light emitting carrier board includes:
a glass substrate, having a plurality of cathode through holes;
a pixel defining layer, arranged on a side of the glass substrate away from the silicon-based driver substrate and having a plurality of pixel openings;
a plurality of sub-pixels, arranged in the plurality of pixel openings; where each of the plurality of sub-pixels includes an anode layer, a light emitting layer and a cathode layer that are stacked sequentially; and
a plurality of isolation structures, protruding out of the pixel defining layer, where each plurality of isolation structures is disposed between two adjacent sub-pixels, of different colors, of the plurality of sub-pixels; each of the plurality of isolation structures includes a conductive portion and a top structure stacked on the conductive portion; the conductive portion is lapped with the cathode layer adjacent thereto.

The light emitting carrier board further includes a cathode auxiliary layer, the cathode auxiliary layer and the anode layer are patterned and formed based on a same conductive layer; in a direction perpendicular to the glass substrate, the conductive portion extends through the pixel defining layer to be electrically connected to the cathode auxiliary layer; the cathode auxiliary layer extends through the plurality of cathode through holes to be electrically connected to the silicon-based driver substrate.

In a second aspect, a display device is provided and includes a motherboard and the display panel of the first aspect.

### BRIEF DESCRIPTION OF THE DRAWINGS

To more clearly illustrate technical solutions in the embodiments of the present disclosure or the related art, the accompanying drawings needed for describing the embodiments of the present disclosure or the related art will be briefly introduced in the following. Obviously, the drawings in the following description are only some embodiments of the present disclosure, and any ordinary skilled person in the art may obtain other drawings based on these drawings without creative work.

FIG. 1 is a structural schematic view of a display panel according to an embodiment of the present disclosure.

FIG. 2 is a cross-sectional view of the display panel shown in FIG. 1, taken along a line E-E.

FIG. 3 is a structural schematic view of a pixel structure according to an embodiment of the present disclosure.

FIG. 4 is a structural schematic view of the pixel structure according to another embodiment of the present disclosure.

FIG. 5 is a structural schematic view of arrangement of an anode through hole, a cathode through hole, and an isolation structure, according to an embodiment of the present disclosure.

FIG. 6 is an enlarged view of a portion F shown in FIG. 5.

FIG. 7 is a structural schematic view of arrangement of a cathode electrode layer, a cathode through hole, and an anode through hole, according to an embodiment of the present disclosure.

FIG. 8 is a structural schematic view of a display device according to an embodiment of the present disclosure.

### REFERENCE NUMERALS IN THE DRAWINGS

100, display panel; 10, silicon-based driver substrate; 11, silicon substrate; 12, driver circuit layer; 20, light emitting carrier board; 21, glass substrate; 211, cathode through hole; 212, anode through hole; 22, pixel defining layer; 220, pixel opening; 221, first pixel defining layer; 222, second pixel defining layer; 23, sub-pixel; 231, anode layer; 232, light emitting layer; 233, cathode layer; 231a, first sub-pixel; 231b, second sub-pixel; 231c, third sub-pixel; 234, pixel unit; 235, pixel structure; 24, isolated structure; 241, conductive portion; 242, top structure; 242A, support; 242B, eave structure; 25, cathode auxiliary layer; 26, cathode electrode layer; 260, hollow portion; 27, anode electrode block; 28, encapsulation layer; 281, organic encapsulation layer; 282, inorganic encapsulation layer; 200, motherboard; 300, display device.

### DETAILED DESCRIPTIONS

Technical solutions of the present disclosure will be described in detail by referring to the accompanying drawings.

In the following description, specific details such as particular system structures, interfaces, techniques, and the like are provided for the purpose of illustration and not for limitation, in order to provide a thorough understanding of the present disclosure.

The technical solutions in the embodiments of the present disclosure will be clearly and completely described below by referring to the accompanying drawings in the embodiments of the present disclosure. Apparently, the described embodiments are only a part of, not all of, the embodiments of the present disclosure. All other embodiments, which are obtained by any ordinary skilled person in the art based on the embodiments in the present disclosure without making creative work, shall fall within the scope of the present disclosure.

Terms “first”, “second”, and “third” in the present disclosure are used for descriptive purposes only and are not to indicate or imply relative importance or implicitly specifying the number of technical features. Therefore, a feature defined with “first”, “second”, “third” may include at least one such feature, either explicitly or implicitly. In the description of the present disclosure, “a plurality of” means at least two, such as two, three, and so on, unless otherwise expressly and specifically limited. All directional indications (such as up, down, left, right, front, rear . . . ) in the embodiments of the present disclosure are only used to explain a relative positional relationship and movement between components at a particular attitude (the attitude as shown in the accompanying drawings). The directional indication may be changed accordingly when the particular attitude is changed. Furthermore, terms “include” and “have” and any variations thereof are intended to cover non-exclusive inclusion. For example, a process, a method, a system, a product or an apparatus including a series of steps or units is not limited to the listed steps or units, but may further include steps or units that are not listed or steps or units that are inherently included in the process, the method, the system, the product or the apparatus.

Reference to “embodiments” herein means that particular features, structures, or characteristics described in an embodiment may be included in at least one embodiment of the present disclosure. The phrase at various sections in the specification does not necessarily refer to one same embodiment, nor separate or alternative embodiments that are mutually exclusive of other embodiments. Any ordinary skilled person in the art shall understand that, both explicitly and implicitly, the embodiments described herein may be combined with other embodiments.

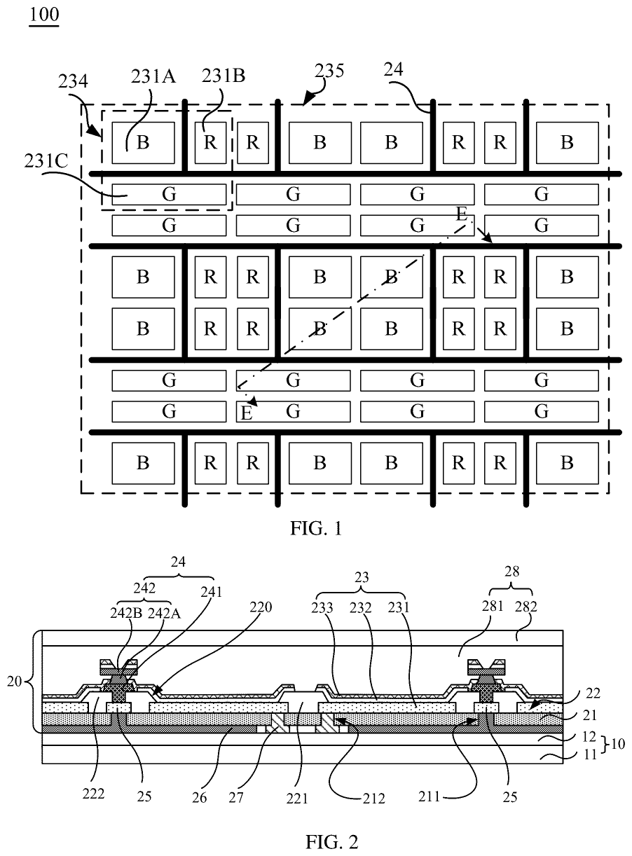

As shown in FIG. 1 and FIG. 2, FIG. 1 is a structural schematic view of a display panel according to an embodiment of the present disclosure; and FIG. 2 is a cross-sectional view of the display panel shown in FIG. 1, taken along a line E-E.

The present disclosure provides a display panel 100. The display panel 100 includes a silicon-based driver substrate 10 and a light emitting carrier board 20. The light emitting carrier board 20 is bonded to the silicon-based driver substrate 10. The light emitting carrier board 20 includes a glass substrate 21, a pixel defining layer 22, a plurality of sub-pixels 23, and a plurality of isolation structures 24. The glass substrate 21 has a plurality of cathode through holes 211. The pixel defining layer 22 is disposed on a side of the glass substrate 21 away from the silicon-based driver substrate 10 and has a plurality of pixel openings 220. Each of the plurality of sub-pixels 23 is disposed in a respective one of the plurality of pixel openings 220. The sub-pixel 23 includes an anode layer 231, a light emitting layer 232, and a cathode layer 233, that are stacked sequentially. Each of the plurality of isolation structure 24 is protruding from the pixel defining layer 22 and is disposed between two adjacent sub-pixels 23 of different colors. The isolation structure 24 includes a conductive portion 241 and a top structure 242 stacked on the conductive portion 241. The cathode layer 233 is lapped with the conductive portion 241 to achieve electrical connection between the cathode layer 233 of one of the two adjacent sub-pixels 23 and the cathode layer 233 of the other one of the two adjacent sub-pixels 23. The light emitting carrier board 20 further includes a cathode auxiliary layer 25, the cathode auxiliary layer 25 and the anode layer 231 are patterned and formed based on a same conductive layer. In a direction perpendicular to the glass substrate 21, the conductive portion 241 extends through the pixel defining layer 22 to be electrically connected with the cathode auxiliary layer 25. The cathode auxiliary layer 25 is electrically connected with the silicon-based driver substrate 10 through the cathode through hole 211.

By separately preparing the light emitting carrier board 20 arranged with the sub-pixels 23 and the silicon-based driver substrate 10 and then bonding the light emitting carrier board 20 to the silicon-based driver substrate 10, the sub-pixels do not need to be directly prepared on the silicon-based driver substrate 10, an influence on a driver circuit layer 12 in the silicon-based driver substrate 10, during vaporization to obtain the sub-pixels 23, may be reduced, such that any loss caused by errors of a subsequent process may be reduced, and manufacturing costs of the silicon-based driver substrate 10 may be reduced. In addition, the isolation structure 24 is disposed between sub-pixels 23 of different colors to electrically connect cathode layers 233 of the sub pixels 23 of different colors to each other, and the conductive portion 241 and the cathode layer 233 cooperatively form a planar cathode. The conductive portion 241 of the isolation structure 24 is electrically connected to the silicon-based driver substrate 10 to reduce connection resistance between the cathode layers 233. In this way, a resistance of the planar cathode may be reduced, a voltage drop may be eliminated, facilitating displaying uniformity of the sub-pixels 23.

The silicon-based driver substrate 10 includes a silicon substrate 11 and a driver circuit layer 12. The driver circuit layer 12 is disposed on a side of the silicon substrate 11 near the light emitting carrier board 20. The silicon substrate 11 refers to a substrate plate taking monocrystalline silicon as a basic material. The driver circuit layer 12 includes an active driver circuit (not shown) integrated on the silicon substrate 11 based on the CMOS process.

The silicon-based driver substrate 10 is prepared separately from the light emitting carrier board 20, such that a production efficiency can be improved. In addition, an effect, caused by the vaporization process, on the silicon-based driver substrate 10 can be reduced, and a loss of the silicon-based driver substrate 10 can be reduced. In other words, from the perspective of processing, separate preparation of the silicon-based driver substrate 10 and the light emitting carrier board 20 improves a product yield and reduces manufacturing costs.

The glass substrate 21 also has a plurality of anode through holes 212 spaced apart from the cathode through holes 211. The anode layer 231 is electrically connected with the silicon-based driver substrate 10 through the anode through-holes 212. The cathode through holes 211 and the anode through holes 212 are all formed by performing a Through-Glass Via (TGV) process.

It is understood that the TGV has excellent high-frequency electrical performance, lower costs, and simpler processes, and higher mechanical stability, compared to a silicon via process.

Compared to the art in which the sub-pixels 23 are prepared on the silicon-based driver substrate 10 and the electrical connection to the silicon-based driver substrate 10 is achieved through the silicon via process, in the present disclosure, the sub-pixels 23 are formed on the glass substrate 21 and are bonded to the silicon-based driver substrate 10 through the TGV, such that the manufacturing costs are reduced, and the high-frequency electrical performance can be improved.

The display panel 100 in the present embodiment includes the plurality of sub-pixels 23 in a plurality of colors. The sub-pixels 23 are OLEDs. The colors of the sub-pixels 23 are not limited herein and can be determined according to the actual needs.

In some embodiments, each of the plurality of sub-pixels 23 is 6 μm to 15 μm. It should be understood that the size of the sub-pixel 23 may be in other values.

In the present embodiment, the display panel 100 including sub-pixels 23 of three different colors will be described as an example.

Specifically, the plurality of sub-pixels 23 include at least one first sub-pixel 231A, at least one second sub-pixel 231B, and at least one third sub-pixel 231C, having three different colors. More than one of the at least one first sub-pixel 231A, more than one of the at least one second sub-pixel 231B, and more than one of the at least one third sub-pixel 231C form a plurality of pixel units 234. Specifically, a respective one of the more than one first sub-pixels 231A, a respective one of the more than one second sub-pixels 231B, and a respective one of the more than one third sub-pixels 231C cooperatively form a respective one of the plurality of pixel units 234. Each of the plurality of pixel units 234 is rectangular in a direction parallel to the glass substrate 21. and the plurality of pixel units 234 are arranged in an array to form a pixel structure 235. Every two adjacent pixel units 234 of the plurality of pixel units 234 in one row of the array are configured in mirror to each other; and every two adjacent pixel units 234 of the plurality of pixel units 234 in one column of the array are configured in mirror to each other. An edge of the pixel structure 235 includes sub-pixels 23 of at least two different colors

It should be noted that the at least one first sub-pixel 231A is in one color, the at least one second sub-pixel 231B is in another one color, and the at least one third sub-pixel 231C is in still another one color.

Each of two adjacent pixel units 234 are arranged in mirror to each other, such that a portion of the plurality of sub-pixels 23 of a same color can be arranged adjacent to each other to reduce the number of the plurality of isolation structures 24, facilitating enhancing a pixel opening rate.

The edge of the pixel structure 235 includes sub-pixels 23 in at least two different colors, such that a visual effect of colored edges, which may affect a displaying effect of the display panel 100, may be avoided.

It should be understood that, among the plurality of rectangular pixel units 234, only when at least two side edges include the sub-pixels 23 in at least two different colors, the edge of the pixel structure 235 can include the sub-pixels 23 in at least two different colors.

In the present embodiment, a light emitting area of the first sub-pixel 231A is greater than a light emitting area of the second sub-pixel 231B and greater than a light emitting area of the third sub-pixel 231C. The first sub-pixel 231A is a blue pixel. One of the second sub-pixel 231B and the third sub-pixel 231C is a red pixel and the other one of the second sub-pixel 231B and the third sub-pixel 231C is a green pixel. In each pixel unit 234, the first sub-pixel 231A and the second sub-pixel 231B are disposed side by side along a row direction of the array of the plurality of pixel units 234 and are disposed on a side of the third sub-pixel 231C along a column direction of the array of the plurality of pixel units 234.

Specifically, each sub-pixel 23 is rectangular. The second sub-pixel 231B is the red pixel, and the third sub-pixel 231C is the green pixel. The light emitting area of the first sub-pixel 231A is configured to be a maximum light emitting area, such that a workload of each blue pixel is reduced, and a service life is extended, and brightness decay may be reduced. A side of the first sub-pixel 231A away from the third sub-pixel 231C is aligned with a side of the second sub-pixel 231B away from the third sub-pixel 231C. A side edge of the first sub-pixel 231A away from the second sub-pixel 231B is aligned with a side edge of the third sub-pixel 231C. The above arrangement of the plurality of sub-pixels 23 allows as many sub-pixels 23 of the same color as possible to be arranged adjacent to each other, further enhancing the pixel opening rate and eliminating the effect of colored edges.

As shown in FIGS. 1 to 4, FIG. 3 is a structural schematic view of the pixel structure according to an embodiment of the present disclosure; and FIG. 4 is a structural schematic view of the pixel structure according to another embodiment of the present disclosure.

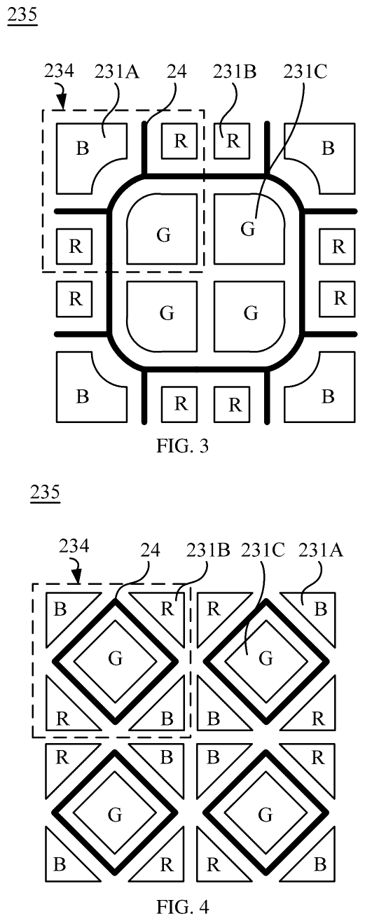

In other embodiments, the sub-pixels 23 in one pixel unit 234 may be arranged in other ways, and the sub-pixel 23 may be configured in other shapes. One pixel unit 234 may include more than one sub-pixels 23 of a same color. For example, as shown in FIG. 3, in one pixel unit 234, the first sub-pixel 231A and the third sub-pixel 231C are disposed diagonally to each other; and two second sub-pixels 231B are disposed diagonally to each other. The first sub-pixel 231A and one of the two second sub-pixels 231B are arranged in the row direction along the pixel units 234, and the first sub-pixel 231A and the third sub-pixel 231C are arranged in the column direction along the pixel units 234. Shapes of the sub-pixels 23 in one pixel unit 234 are complementary to each other to enable the pixel unit 234 to be rectangular, such that the plurality of pixel units 234 may be easily arranged. In another example, as shown in FIG. 4, in one pixel unit 234, the first sub-pixels 231A and the second sub-pixels 231B are arranged along the row direction and the column direction of the pixel units 234. Each of the first sub-pixel 231A and the second sub-pixel 231B is in a shape of a right triangle and is located at a respective corner of the rectangular pixel unit 234. The third sub-pixel 231C is rhombus shaped and located at a center of the pixel unit 234.

A portion of the pixel defining layer 22 disposed between two adjacent sub-pixels 23 of the same color is defined as a first pixel defining layer 221, and another portion of the pixel defining layer 22 disposed between two adjacent sub-pixels 23 of different colors is defined as a second pixel defining layer 222. A width of the first pixel defining layer 221 is smaller than a width of the second pixel defining layer 222.

It is understood that the isolation structures 24 are arranged on the second pixel defining layer 222, instead of being arranged on the first pixel defining layer 221, enabling the width of the first pixel defining layer 221 to be smaller than the width of the second pixel defining layer 222. Since the isolation structures 24 are not arranged on the first pixel definition layer 221, the width of the first pixel definition layer 221 may be minimized according to an exposure limit of an exposure machine and a photoresist (PR) adhesive development limit, such that the width of the first pixel definition layer 221 can be significantly small. Furthermore, under requirements of high Pixels Per Inch (PPI), a spacing between anode layers 231 may be as low as 2 μm to 3 μm, such that increasing the pixel opening 220 can e achieved.

In other words, no isolation structure 24 is arranged between two adjacent sub-pixels 23 of the same color, and the spacing between two adjacent sub-pixels 23 of the same color is smaller than the spacing between two adjacent sub-pixels 23 of different colors, and in this way, the pixel opening rate is further improved.

The second pixel defining layer 222 covers the cathode auxiliary layer 25 and enables the anode layer 231 to be insulated from the cathode auxiliary layer 25.

The isolation structure 24 is configured to isolate sub-pixels 23 of different colors from each other to prevent optical crosstalk between the sub-pixels 23 of different colors. Compared to the art in which the sub-pixels 23 are prepared using a Fine Metal Mask (FMM) process, in the present embodiment, the sub-pixels 23 are isolated from each other by the isolation structure 24, such that the FMM is omitted, the manufacturing costs are reduced.

In a direction parallel to the glass substrate 21, the top structure 242 extends out of the conductive portion 241. An orthographic projection of the top structure 242 on the glass substrate 21 covers an orthographic projection of the cathode through hole 211 on the glass substrate 21, such that the cathode through hole 211 does not occupy a position wherein the anode layer 231 is arranged.

The top structure 242 of the isolation structure 24 includes a support 242A and an eave structure 242B. The support 242A is disposed on an upper surface of the conductive portion 241 and supports the eave structure 242B. The eave structure 242B extends out of an edge of the conductive portion 241, so as to adjust an evaporation angle for obtaining the sub-pixel 23 to allow the cathode layer 233 of the sub-pixel 23 to cover the light emitting layer 232 of the sub-pixel 23 and to achieve proper lapping with the conductive portion 241. An orthographic projection of the top structure 242 on the pixel defining layer 22 covers an orthographic projection of the conductive portion 241 on the pixel defining layer 22.

In a direction parallel to the pixel defining layer 22, the eave structure 242B extends out of the upper surface of the support 242A. The support 242A is arranged to reduce a thickness of the portion of the conductive portion 241 protruding out of the pixel defining layer 22. In this way, the conductive portion 241, which is opaque, is prevented from blocking light laterally emitted from the sub-pixel 23, such that reduction in a light utilization rate of the sub-pixel 23 is avoided. Furthermore, the cathode layer 233 may climb easily to properly lap with the conductive portion 241.

The conductive portion 241 is T-shaped. A portion of the conductive portion 241 is inserted inside the pixel defining layer 22 to enhance stability of the conductive portion 241. Another portion of the conductive portion 241 protrudes out of the upper surface of the pixel defining layer 22 to facilitate lapping between the sub-pixel 23 and the conductive portion 241.

The conductive portion 241 of the isolation structure 24 laps with the cathode layer 233 to electrically connect cathode layers 23 of sub-pixels 23 of different colors with each other to form a planar cathode.

To be noted that in the present embodiment, cathode layers 233 of two adjacent sub-pixels 23, which are in the same color and are arranged on the upper surface of the first pixel defining layer 221, are insulated from each other and are spaced apart from each other. Light emitting layers 232 of two adjacent sub-pixels 23, which are in the same color and are arranged on the upper surface of the first pixel defining layer 221, are spaced apart from each other. In this way, the light emitting layers 232 of the two adjacent sub-pixels 23 of two colors are disconnected from each other, such that the displaying effect of the display panel 100 is improved.

The cathode auxiliary layer 25 and the anode layer 231 are patterned and formed based on a same conductive layer, such that a preparation process is simplified.

An orthographic projection of the cathode auxiliary layer 25 on the glass substrate 21 covers the cathode through hole 211 to avoid the cathode through hole 211 from being excessively large to be short-circuited with the anode layer 231, such that the displaying effect of the display panel 100 is not affected.

The anode through hole 212 and the anode layer 231 are in one-to-one correspondence with each other. In the direction parallel to the glass substrate 21, the anode through hole 212 is located near the first pixel defining layer 221. In this way, the plurality of anode through holes 212 are concentrated near the first pixel defining layer 221, reducing a loss of the pixel opening rate. Furthermore, the plurality of anode through holes 212 are located as away as possible from the plurality of cathode through holes 211, such that a plurality of cathode auxiliary layers 25 are concentratively distributed. In this way, a planar cathode electrode layer 26 may be prepared easily, ensuring that an area of the cathode electrode layer 26 is maximized, and an impedance of the planar cathode may be reduced.

Adjacent isolation structures 24 of the plurality of isolation structures 24 are partially overlapped with each other. The cathode through hole 211 directly faces an overlapped portion between the adjacent isolation structures 24 in the direction perpendicular to the glass substrate 21. In this way, the cathode through hole 211 is prevented from occupying a position where the anode layer 231 is arranged, and the pixel opening rate is not affected. Specifically, the portion of the conductive portion 241 inserted into the pixel defining layer 22 is in contact with the upper surface of the cathode auxiliary layer 25 to avoid excessively occupying the gap between the sub-pixels 23. An orthographic projection of the portion of the conductive portion 241 inserted into the pixel defining layer 22 on the cathode auxiliary layer 25 is disposed within the cathode auxiliary layer 25 to prevent a short circuit between the conductive portion 241 and the anode, such that the displaying effect of the display panel 100 is not affected.

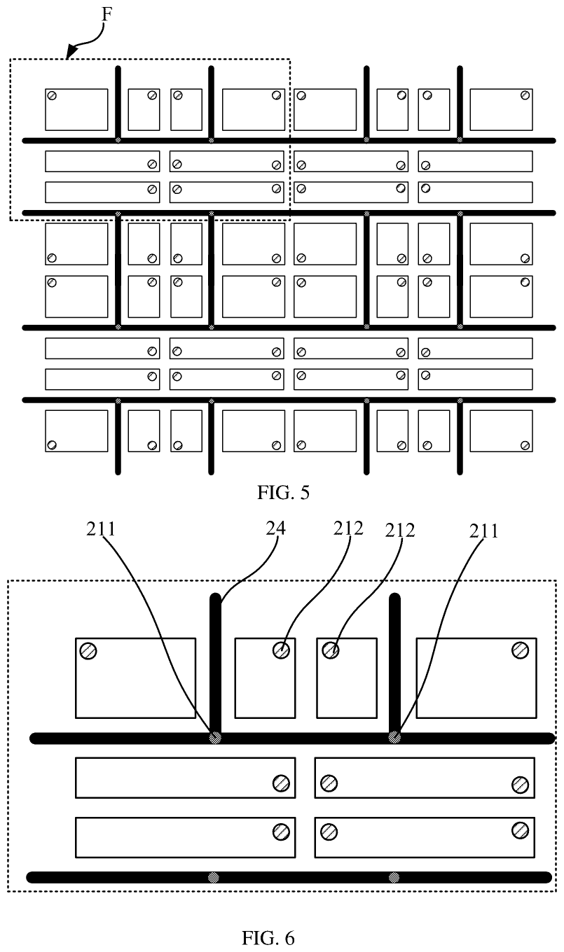

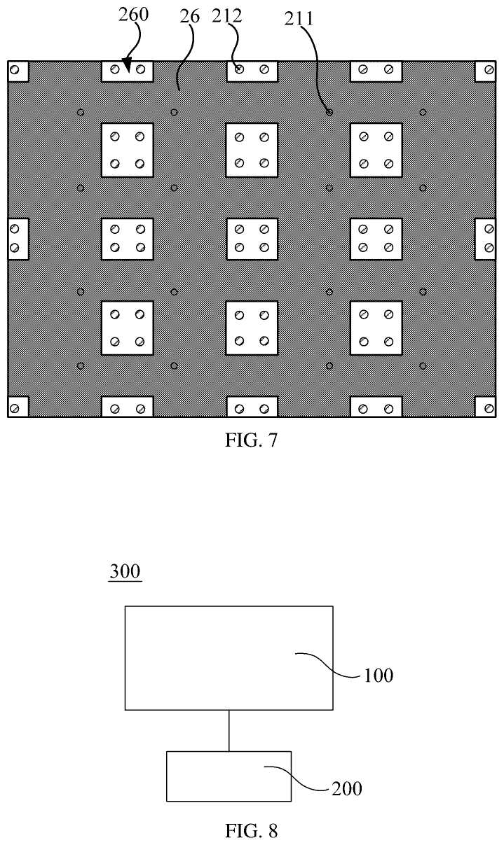

As shown in FIGS. 1 to 7, FIG. 5 is a structural schematic view of arrangement of the anode through hole, the cathode through hole, and the isolation structure, according to an embodiment of the present disclosure; FIG. 6 is an enlarged view of a portion F shown in FIG. 5; and FIG. 7 is a structural schematic view of arrangement of the cathode electrode layer, the cathode through hole, and the anode through hole, according to an embodiment of the present disclosure.

The light emitting carrier board 20 further includes a cathode electrode layer 26 and an anode electrode block 27 insulated from the cathode electrode layer 26. The cathode electrode layer 26 and the anode electrode block 27 are both arranged on a side of the glass substrate 21 away from the isolation structure 24.

The anode electrode block 27 fills the anode through hole 212 and is bonded to the silicon-based driver substrate 10. The cathode electrode layer 26 fills the cathode through hole 211 and is bonded to the silicon-based driver substrate 10.

The anode electrode block 27 and the cathode electrode layer 26 are provided insulated. Materials of the anode electrode block 27 and the cathode electrode layer 26 are not limited herein and can be determined according to actual needs.

In the present embodiment, the anode electrode block 27 and the cathode electrode layer 26 are formed by patterning a same electrically conductive material layer, such that the preparation process is simplified.

An area of the cathode electrode layer 26 is greater than an area of the anode electrode block 27. The cathode electrode layer 26 is an integral planar electrode, having a plurality of hollow portions 260. The anode electrode block is disposed in the plurality of hollow portions 260. Since the cathode electrode layer 26 is configured as the integral planar electrode, the cathode electrode layer 26 is electrically connected to the conductive portion 241, the impedance of the planar cathode can be further reduced.

As shown in FIG. 2, the isolation structure 24 is not disposed between third sub-pixels 231C of two adjacent rows of the array. In this way, cathode layers 233 of the sub-pixels 23 in the two adjacent rows of the third sub-pixels 231C are not electrically connected to each other, such that cathode layers 233 of all sub-pixels 23 are not electrically connected to each other, homogeneity of all cathode layers 233 is not optimized. In the art, another layer of cathode layer 233 may be arranged to enable cathode layers 233 of two adjacent sub-pixels 23, which are in the same color and are disposed on the upper surface of the first pixel defining layer 221, to be lapped with each other to be electrically connected to each other.

The conductive portion 241 of the isolation structure 24 is electrically connected to the cathode auxiliary layer 25. The cathode auxiliary layer 25 is electrically connected to the cathode electrode layer 26 through the cathode through hole 211, such that all cathode layers 233 that are lapped with the conductive portion 241 are electrically connected with the cathode layer 233. Furthermore, the cathode electrode layer 26 is configured as the integral planar electrode, such that all cathode layers 233 can be electrically connect with each other, and the another layer of cathode layers 233, which may be arranged to lap the cathode layers 233 of two adjacent sub-pixels 23 that are in the same color and are disposed on the upper surface of the first pixel defining layer 221 to achieve electrical connection, can be omitted, and process steps may be reduced.

The light emitting carrier board 20 further includes an encapsulation layer 28, the encapsulation layer 28 is disposed on a side of the isolation structure 24 away from the glass substrate 21. The encapsulation layer 28 includes an organic encapsulation layer 281 and an inorganic encapsulation layer 282, the organic encapsulation layer 281 encapsulates the sub-pixel 23 and the isolation structure 24, and a side of the organic encapsulation layer 281 away from the glass substrate 21 is planarized. The inorganic encapsulation layer 282 is arranged on a side of the organic encapsulation layer 281 away from the glass substrate 21.

Materials of the organic encapsulation layer 281 and the inorganic encapsulation layer 282 are not limited herein and can be determined according to actual needs.

As shown in FIG. 8, FIG. 8 is a structural schematic view of a display device according to an embodiment of the present disclosure.

The present disclosure provides a display device 300. The display device 300 includes a motherboard 200 and the display panel 100 as described above. The display device 300 of the present embodiment is an AMOLED.

The motherboard 200 is electrically connected to the display panel 100, and the motherboard 200 is configured to transmit various signals to the display panel 100 to control the display panel 100 to display an image. For example, the various signals may include: a clock signal (CK), a low potential signal (Vss), a power supply voltage signal (VDD), and a data signal required by the driver circuit layer.

In the above embodiments, description of each embodiment has its own focus, and parts that are not detailed in one embodiment may be referred to the relevant descriptions of other embodiments.

The above is only an implementation of the present disclosure, and is not intended to limit the scope of the present disclosure. Any equivalent structure or equivalent process transformation performed based on the contents of the specification and the accompanying drawings of the present disclosure, applied directly or indirectly in other related technical fields, shall be equivalently included in the scope of the present disclosure.

What is claimed is:

1. A display panel, comprising:
a silicon-based driver substrate;
a light emitting carrier board, bonded and connected to the silicon-based driver substrate; wherein the light emitting carrier board comprises:
a glass substrate, having a plurality of cathode through holes;
a pixel defining layer, arranged on a side of the glass substrate away from the silicon-based driver substrate and having a plurality of pixel openings;
a plurality of sub-pixels, arranged in the plurality of pixel openings; wherein each of the plurality of sub-pixels comprises an anode layer, a light emitting layer and a cathode layer that are stacked sequentially; and
a plurality of isolation structures, protruding out of the pixel defining layer, wherein each plurality of isolation structures is disposed between two adjacent sub-pixels, of different colors, of the plurality of sub-pixels; each of the plurality of isolation structures comprises a conductive portion and a top structure stacked on the conductive portion; the conductive portion is lapped with the cathode layer adjacent thereto;
wherein the light emitting carrier board further comprises a cathode auxiliary layer, the cathode auxiliary layer and the anode layer are patterned and formed based on a same conductive layer; in a direction perpendicular to the glass substrate, the conductive portion extends through the pixel defining layer to be electrically connected to the cathode auxiliary layer; the cathode auxiliary layer extends through the plurality of cathode through holes to be electrically connected to the silicon-based driver substrate.

2. The display panel according to claim 1, wherein a portion of the pixel defining layer disposed between two adjacent sub-pixels, of a same color, of the plurality of sub-pixels is defined as a first pixel defining layer; and another portion of the pixel defining layer disposed between two adjacent sub-pixels, of different colors, of the plurality of sub-pixels is defined as a second pixel defining layer; a width of the first pixel defining layer is less than a width of the second pixel defining layer.

3. The display panel according to claim 2, wherein the glass substrate further has a plurality of anode through holes spaced from the plurality of cathode through holes, and the anode layer of each of the plurality of sub-pixels is electrically connected with the silicon-based driver substrate through a respective one of the plurality of anode through holes;
each of the plurality of anode through holes is corresponding to the anode layer of one respective of the plurality of sub-pixels; in a direction parallel to the glass substrate, the plurality of anode through holes are arranged near the first pixel defining layer; adjacent isolation structures of the plurality of isolation structures are partially overlapping with each other to form an overlapping portion; in a direction perpendicular to the glass substrate, each respective of the plurality of cathode through holes directly faces the overlapping region.

4. The display panel according to claim 3, wherein the light emitting carrier board further comprises a cathode electrode layer and a plurality of anode electrode blocks insulated from the cathode electrode layer; the cathode electrode layer and the plurality of anode electrode blocks are disposed on a side of the glass substrate away from the plurality of isolation structures;
the plurality of anode electrode blocks fill the plurality of anode through holes and are bonded to the silicon-based driver substrate; the cathode electrode layer fills the plurality of cathode through holes and is bonded to the silicon-based driver substrate; and
an area of the cathode electrode layer is greater than an area of the plurality of anode electrode blocks; the cathode electrode layer is configured as an integral planar electrode, the integral planar electrode has a plurality of hollow portions, and the plurality of anode electrode blocks are received in the plurality of hollow portions.

5. The display panel according to claim 1, wherein the plurality of sub-pixels comprise at least one first sub-pixel, at least one second sub-pixel and at least one third sub-pixel having different colors from each other;
more than one first sub-pixels of the at least one first sub-pixel, more than one second sub-pixels of the at least one second first sub-pixel, and more than one third sub-pixels of the at least one third first sub-pixel form a plurality of pixel units;
a respective one of the more than one first sub-pixels, a respective one of the more than one second sub-pixels, and a respective one of the more than one third sub-pixels form a respective one of the plurality of pixel units;
the plurality of pixel units are arranged into an arrayed to form a pixel structure; every two adjacent pixel units of the plurality of pixel units in one row of the array are configured in mirror to each other, and every two adjacent pixel units of the plurality of pixel units in one column of the array are configured in mirror to each other; an edge of the pixel structure includes sub-pixels in at least two different colors.

6. The display panel according to claim 5, wherein a light emitting area of the first sub-pixel is greater than a light emitting area of the second sub-pixel and greater than a light emitting area of the third sub-pixel; the first sub-pixel is a blue pixel; one of the second sub-pixel and the third sub-pixel is a red pixel; and the other one of the second sub-pixel and the third sub-pixel is a green pixel;
in each of the plurality of pixel units, the first sub-pixel and the second sub-pixel are arranged side by side along a row direction of the array of the plurality of pixel units and are disposed on one side of the third sub-pixel along a column direction of the array of the plurality of pixel units.

7. The display panel according to claim 1, wherein the silicon-based driver substrate comprises a silicon substrate and a driver circuit layer, the driver circuit layer is disposed on a side of the silicon substrate near the light emitting carrier board.

8. The display panel according to claim 1, wherein in a direction parallel to the glass substrate, the top structure extends out of the conductive portion; an orthographic projection of the top structure on the glass substrate covers an orthographic projection of a respective one of the plurality of cathode through holes on the glass substrate.

9. The display panel according to claim 1, wherein the light emitting carrier board further comprises an encapsulation layer, the encapsulation layer is located on a side of the isolation structure away from the glass substrate.

10. A display device, comprising a motherboard and a display panel; wherein the display panel comprises a silicon-based driver substrate; and a light emitting carrier board, bonded and connected to the silicon-based driver substrate; wherein the light emitting carrier board comprises:
a glass substrate, having a plurality of cathode through holes;
a pixel defining layer, arranged on a side of the glass substrate away from the silicon-based driver substrate and having a plurality of pixel openings;
a plurality of sub-pixels, arranged in the plurality of pixel openings; wherein each of the plurality of sub-pixels comprises an anode layer, a light emitting layer and a cathode layer that are stacked sequentially; and
a plurality of isolation structures, protruding out of the pixel defining layer, wherein each plurality of isolation structures is disposed between two adjacent sub-pixels, of different colors, of the plurality of sub-pixels; each of the plurality of isolation structures comprises a conductive portion and a top structure stacked on the conductive portion; the conductive portion is lapped with the cathode layer adjacent thereto;
wherein the light emitting carrier board further comprises a cathode auxiliary layer, the cathode auxiliary layer and the anode layer are patterned and formed based on a same conductive layer; in a direction perpendicular to the glass substrate, the conductive portion extends through the pixel defining layer to be electrically connected to the cathode auxiliary layer; the cathode auxiliary layer extends through the plurality of cathode through holes to be electrically connected to the silicon-based driver substrate.

11. The display device according to claim 10, wherein a portion of the pixel defining layer disposed between two adjacent sub-pixels, of a same color, of the plurality of sub-pixels is defined as a first pixel defining layer; and another portion of the pixel defining layer disposed between two adjacent sub-pixels, of different colors, of the plurality of sub-pixels is defined as a second pixel defining layer; a width of the first pixel defining layer is less than a width of the second pixel defining layer.

12. The display device according to claim 11, wherein the glass substrate further has a plurality of anode through holes spaced from the plurality of cathode through holes, and the anode layer of each of the plurality of sub-pixels is electrically connected with the silicon-based driver substrate through a respective one of the plurality of anode through holes;
each of the plurality of anode through holes is corresponding to the anode layer of one respective of the plurality of sub-pixels; in a direction parallel to the glass substrate, the plurality of anode through holes are arranged near the first pixel defining layer; adjacent isolation structures of the plurality of isolation structures are partially overlapping with each other to form an overlapping portion; in a direction perpendicular to the glass substrate, each respective of the plurality of cathode through holes directly faces the overlapping region.

13. The display device according to claim 12, wherein the light emitting carrier board further comprises a cathode electrode layer and a plurality of anode electrode blocks insulated from the cathode electrode layer; the cathode electrode layer and the plurality of anode electrode blocks are disposed on a side of the glass substrate away from the plurality of isolation structures;
the plurality of anode electrode blocks fill the plurality of anode through holes and are bonded to the silicon-based driver substrate; the cathode electrode layer fills the plurality of cathode through holes and is bonded to the silicon-based driver substrate; and
an area of the cathode electrode layer is greater than an area of the plurality of anode electrode blocks; the cathode electrode layer is configured as an integral planar electrode, the integral planar electrode has a plurality of hollow portions, and the plurality of anode electrode blocks are received in the plurality of hollow portions.

14. The display device according to claim 10, wherein the plurality of sub-pixels comprise at least one first sub-pixel, at least one second sub-pixel and at least one third sub-pixel having different colors from each other;
more than one first sub-pixels of the at least one first sub-pixel, more than one second sub-pixels of the at least one second first sub-pixel, and more than one third sub-pixels of the at least one third first sub-pixel form a plurality of pixel units;
a respective one of the more than one first sub-pixels, a respective one of the more than one second sub-pixels, and a respective one of the more than one third sub-pixels form a respective one of the plurality of pixel units;
the plurality of pixel units are arranged into an arrayed to form a pixel structure; every two adjacent pixel units of the plurality of pixel units in one row of the array are configured in mirror to each other, and every two adjacent pixel units of the plurality of pixel units in one column of the array are configured in mirror to each other; an edge of the pixel structure includes sub-pixels in at least two different colors.

15. The display device according to claim 14, wherein a light emitting area of the first sub-pixel is greater than a light emitting area of the second sub-pixel and greater than a light emitting area of the third sub-pixel; the first sub-pixel is a blue pixel; one of the second sub-pixel and the third sub-pixel is a red pixel; and the other one of the second sub-pixel and the third sub-pixel is a green pixel;
in each of the plurality of pixel units, the first sub-pixel and the second sub-pixel are arranged side by side along a row direction of the array of the plurality of pixel units and are disposed on one side of the third sub-pixel along a column direction of the array of the plurality of pixel units.

16. The display device according to claim 10, wherein the silicon-based driver substrate comprises a silicon substrate and a driver circuit layer, the driver circuit layer is disposed on a side of the silicon substrate near the light emitting carrier board.

17. The display device according to claim 10, wherein in a direction parallel to the glass substrate, the top structure extends out of the conductive portion; an orthographic projection of the top structure on the glass substrate covers an orthographic projection of a respective one of the plurality of cathode through holes on the glass substrate.

18. The display device according to claim 10, wherein the light emitting carrier board further comprises an encapsulation layer, the encapsulation layer is located on a side of the isolation structure away from the glass substrate.

19. The display device according to claim 10, wherein a portion of the conductive portion is inserted into the pixel defining layer and is in contact with an upper surface of the cathode auxiliary layer.

20. The display device according to claim 11, wherein the cathode layer of one of the two adjacent sub-pixels having the same color is insulated from and spaced apart from the cathode layer of the other one of the two adjacent sub-pixels having the same color; and the light emitting layer of one of the two adjacent sub-pixels having the same color is spaced apart from the light emitting layer of the other one of the two adjacent sub-pixels having the same color.
